(19) United States
(12) Patent Application Publication
(10) Pub. No.: US 2025/0234764 A1
(43) Pub. Date: Jul. 17, 2025

(54) DISPLAY APPARATUS AND VISION INSPECTION SYSTEM

(71) Applicant: SAMSUNG DISPLAY CO., LTD., Yongin-si (KR)

(72) Inventors: Hyoseok Yang, Yongin-si (KR); Youngmoo Kwon, Yongin-si (KR); Heesung Lim, Yongin-si (KR)

(21) Appl. No.: 18/777,340

(22) Filed: Jul. 18, 2024

(30) Foreign Application Priority Data
Jan. 17, 2024 (KR) 10-2024-0007631

(51) Int. Cl. H10K 59/80

(52) U.S. Cl. CPC H10K 59/8793; H10K 59/871; H10K 59/8792

(57) ABSTRACT

A display apparatus includes a pixel circuit layer, a polarization layer disposed on the pixel circuit layer, an optical functional layer disposed on the polarization layer, and a reference pattern aligned with an edge of the optical functional layer.

### CROSS-REFERENCE TO RELATED APPLICATION

This application is based on and claims priority under 35 U.S.C. § 119 to Korean Patent Application No. 10-2024-0007631, filed on Jan. 17, 2024, in the Korean Intellectual Property Office, the disclosure of which is incorporated by reference herein in its entirety.

### BACKGROUND

### 1. Technical Field

The inventive concept relates to a display apparatus and a vision inspection system, and more particularly to a display apparatus including a reference pattern indicating a position of an optical functional layer and a polarization layer, and an inspection system for identifying a reference pattern.

### 2. Discussion of Related Art

Display apparatus may receive image data and display an image corresponding to the image data. Such display apparatus may be used as displays of products such as mobile phones or televisions.

Display apparatus may include a plurality of pixels that receive electrical signals and emit light to display an image. Each of the plurality of pixels includes a light-emitting device. For example, in the case of organic light-emitting display apparatus, each pixel may include an organic light-emitting diode (OLED) as a light-emitting device. In general, organic light-emitting display apparatus may include a thin-film transistor and an organic light-emitting diode, formed on a substrate, and the organic light-emitting diode may emit light.

Meanwhile, inspection technologies are being developed to improve the quality of these display apparatus.

### SUMMARY

In one or more embodiments a display apparatus may include a reference pattern for identifying an alignment of an optical functional layer and a polarization layer using an inspection system, and an inspection system may be configured to identify a reference pattern. However, aspects of the disclosure are not limited thereto.

Additional aspects will be apparent from the description which follows, or may be learned by practice of the technical ideas of the inventive concepts presented in the disclosure.

According to one or more embodiments, a display apparatus includes a pixel circuit layer, a polarization layer disposed on the pixel circuit layer, an optical functional layer disposed on the polarization layer, and a reference pattern aligned with an edge of the optical functional layer.

The display apparatus may further include a substrate, wherein the pixel circuit layer may be disposed on the substrate, and the reference pattern may be printed on an upper surface of the optical functional layer.

The display apparatus may further include a protective film layer disposed on the optical functional layer and the reference pattern.

The display apparatus may further include a protective film layer disposed on the optical functional layer, wherein the reference pattern may be printed on a lower surface of the protective film layer.

The display apparatus may further include a protective film layer disposed on the optical functional layer, wherein the reference pattern may be printed on an upper surface of the protective film layer.

The optical functional layer may further include an adhesive layer disposed on the polarization layer, a light control layer disposed on the adhesive layer, and a cover layer disposed on the light control layer.

The reference pattern may be printed on an upper surface of the cover layer.

The reference pattern may have a width of about 10 micrometers to about 150 micrometers in a plan view.

The display apparatus may further include a window layer disposed on the optical functional layer and a light blocking material layer disposed on the window layer that overlaps the reference pattern in a plan view.

The light blocking material layer may be disposed on a lower surface of the window layer.

According to one or more embodiments, a vision inspection system includes a sensing device configured to generates image data about an upper surface of a display panel comprising a polarization layer, an optical functional layer disposed on the polarization layer, and a reference pattern aligned with an edge of the optical functional layer, and a computing device configured to receive the image data, recognize the reference pattern from the image data, and based on the reference pattern, obtain alignment state information of the optical functional layer.

The information on the alignment state may be information corresponding to one of a case in which an edge of the optical functional layer protrudes outside an edge of the polarization layer in the image data, a case in which the edge of the optical functional layer is disposed inside the edge of the polarization layer in the image data, or a case in which the edge of the optical functional layer coincides with the edge of the polarization layer in the image data.

The computing device may be configured to cause the display panel to be advanced to a further process upon obtaining information on the alignment state of the optical functional layer indicating that the edge of the optical functional layer coincides with the edge of the polarization layer in the image data.

The computing device may be configured to cause the display panel to be advanced for one of corrective processing or recycling upon obtaining information on the alignment state of the optical functional layer indicating that the edge of the optical functional layer protrudes outside the edge of the polarization layer in the image data or that the edge of the optical functional layer is disposed inside the edge of the polarization layer in the image data.

According to one or more embodiments, a display apparatus includes a substrate, a pixel circuit layer disposed on the substrate, a polarization layer disposed on the pixel circuit layer, an optical functional layer disposed on the polarization layer, and a reference pattern printed on an upper surface of the optical functional layer at an edge of the optical functional layer.

The display apparatus may further include a protective film disposed on the optical functional layer and the reference pattern.

The optical functional layer may further include an adhesive layer disposed on the polarization layer, a light control layer disposed on the adhesive layer, and a cover layer disposed on the light control layer.

The reference pattern may have a width of about 10 micrometers to about 150 micrometers in a plan view.

The display apparatus may further include a first adhesive layer disposed on the optical functional layer, a window layer disposed on the first adhesive layer, and a light blocking material layer disposed on a surface of the window layer that overlaps the reference pattern in a plan view.

The light blocking material layer may be disposed on a lower surface of the window layer.

### BRIEF DESCRIPTION OF THE DRAWINGS

Aspects, features, and advantages of embodiments of the disclosure will be more apparent from the following description taken in conjunction with the accompanying drawings, in which:

FIG. 1 is a schematic plan view of a display apparatus according to an embodiment;

FIG. 2 is an equivalent circuit diagram of a pixel of the display apparatus of FIG. 1;

FIG. 3 is a plan view mainly showing an optical functional layer of a display panel of FIG. 1;

FIG. 4 is a cross-sectional view schematically showing a cross-section taken along line I-I′ of FIG. 3;

FIG. 5 is a schematic cross-sectional view of a portion of the display apparatus of FIG. 1;

FIGS. 6 through 8 are cross-sectional views schematically showing an example in which a protective film layer is disposed on the optical functional layer of FIG. 3 and FIG. 4;

FIG. 9 is a cross-sectional view schematically showing an example in which a window layer is disposed on the display panel of FIG. 4; and

FIG. 10 is a conceptual diagram schematically illustrating an optical functional layer alignment inspection system according to an embodiment.

### DETAILED DESCRIPTION

Reference will now be made in detail to embodiments, examples of which are illustrated in the accompanying drawings, wherein like reference numerals refer to like elements throughout. In this regard, embodiments may have different forms and should not be construed as being limited to the descriptions set forth herein. Accordingly, embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to embodiments set forth herein.

One or more embodiments will be described below in more detail with reference to the accompanying drawings. Components may be identified by the same reference numeral in the drawings, and redundant explanations thereof may be omitted.

It will be understood that, unless otherwise specified, when an element such as a layer, film, region or substrate is referred to as being “on” another element, it can be “directly” on the other element or intervening elements may also be present. It will be understood that, unless otherwise specified, when an element such as a layer, film, region or substrate is referred to as being “below” another element, it can be “directly” below the other element or intervening elements may also be present.

In the drawings, the thicknesses of layers and regions may be exaggerated or reduced for convenience of explanation. For example, sizes and thicknesses of components in the drawings may be arbitrarily illustrated for convenience of explanation, and embodiments are not limited thereto. That is, for convenience of explanation, sizes, thicknesses, and ratios of components in the drawings may be exaggerated and/or simplified for clarity. Accordingly, spatially relative terms such as “beneath”, “below”, “lower”, “under”, “above”, and “upper” may be used to describe one element or feature's relationship with another element or feature.

In the specification, it will be understood that terms used to describe spaces, directions, etc. are intended to encompass different directions or viewpoints in addition to the spaces or directions shown in the drawings. For example, when a device or a component in the drawings is turned over, the device or component described as “below” may be otherwise oriented (e.g., rotated by 90 degrees or the opposite direction). For example, when a device or a component in the drawings is turned over, the device or component described as “above” may be otherwise oriented (e.g., rotated by 90 degrees or the opposite direction). Accordingly, the terms “below” and “above” may include both orientations of above and below. In addition, a device or a component may be otherwise oriented and descriptions according to spaces or directions used herein may be interpreted in various ways.

In the specification, a process order or a method order in the description of a process or manufacturing method may be different from a described order. For example, two consecutively described processes or methods may be performed substantially at the same time or performed in an order opposite to the described order.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the specification, the terms “first”, “second”, and “third” may be used to describe specific components, and the terms “first”, “second”, and “third” may be used to distinguish one component from another.

When one component is referred to as “connected to” or “coupled to” another component, it may be directly connected to, or coupled to the other component, or one or more intervening component may be present therebetween.

Likewise, when one component is “electrically connected” to another component, the component and the other component may be directly and electrically connected, or may be indirectly and electrically connected through a conductive component.

In addition, it will be understood that when a component is referred to as being “between” other components, the component may be the only component located between the other components, or an intervening component other than the component may be located between the other components.

The terms used in the present specification are merely used to describe particular embodiments, and are not intended to limit the disclosure. The singular terms “a” and “an” used herein are intended to include the plural forms as well unless the context clearly indicates otherwise.

The terms “mixing”, “mixture”, “mix”, “comprises”, “comprising”, “includes”, “including”, “have (has)”, and “having” specify the presence of the described feature, integer, step, operation, element, and/or component, but do not preclude the presence or addition of one or more other features, integers, steps, operations, elements, components, and/or groups thereof.

The term “and/or” includes any and all combinations of one or more of the associated listed items. For example, the expression “A and/or B” indicates A, B, or A and B. The expression “at least one of” may be used to indicate one or more components among a plurality of components. For example, the expression “at least one of a, b, and c” or “at least one selected from the group consisting of a, b, and c” may indicate “a”, “b”, “c”, “a, b”, “b, c”, “a, c”, or “a, b, c”.

The terms such as “substantially” and “about” and similar terms are used as terms of approximation rather than terms of degree, and may be intended to account for inherent deviations in measured or calculated values that would be recognized by one of ordinary skill in the art. For example, the use of the term “may” or “can” when describing embodiments may refer to one or more embodiments disclosed in the specification.

In the specification, when a layer has the “same layer structure” as another layer, it may mean that a plurality of layers included in the layer may be included in the other layer in the same order. For example, a plurality of layers included in a layer and a plurality of layers included in another layer may include the same material and may be formed in the same order.

Electronic or electric devices and/or other related devices or components (e.g., some of various modules) according to embodiments described herein may be implemented by using any suitable hardware, firmware (e.g., application-specific integrated circuit), or software, or a combination of software, firmware, and hardware. For example, various components of these devices may be formed on an integrated circuit (IC) chip or separate IC chips. Further, various components of these devices may be formed on a flexible printed circuit film, a tape carrier package (TCP), a printed circuit board (PCB), or formed on a substrate. Further, various components of these devices may be processes or threads, running on one or more processors, in one or more computing devices, executing compute program instructions, and interacting with other system components for performing various functions described herein.

The computer program instructions may be stored in a memory. The memory may be implemented in a computing device using a standard memory device such as a random-access memory (RAM). The computer program instructions may also be stored in other non-transitory computer-readable media such as a CD-ROM or a flash drive. In addition, one of ordinary skill in the art should recognize that functions of various computing devices may be combined or integrated into a single computing device or that a function of a specific computing device may be distributed across one or more other computing devices without departing from the spirit and scope of the embodiments.

A display apparatus according to an embodiment will be described in detail in the context of the above-described matters.

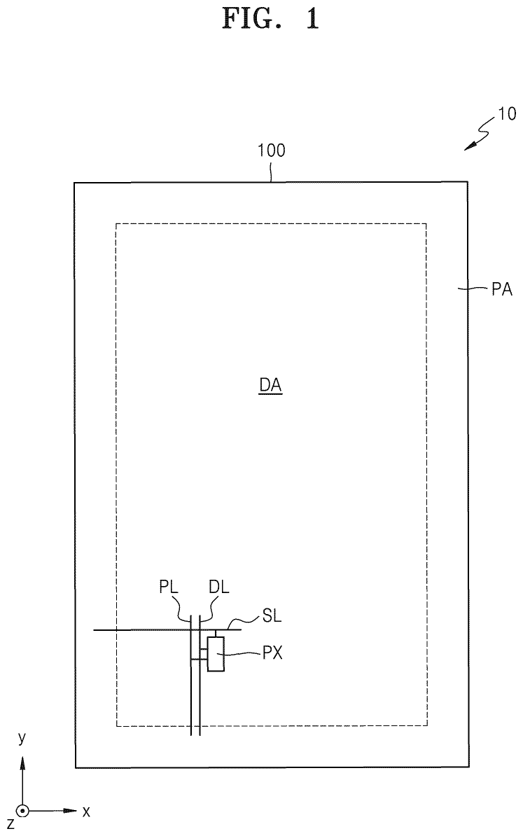

FIG. 1 is a schematic plan view of a display apparatus according to an embodiment.

As illustrated in FIG. 1, the display apparatus according to an embodiment may include a display panel 10. The display apparatus may be of any type as long as it includes the display panel 10. For example, the display apparatus may be a device such as a smartphone, a tablet, a laptop, a television, or a digital billboard. The display apparatus according to an embodiment may include thin-film transistors and a capacitor, and the thin-film transistors and the capacitor may be implemented by conductive layers and insulating layers.

The display panel 10 may include a display area DA. The display panel 10 may include a peripheral area PA disposed around the display area DA. Although FIG. 1 illustrates that the display area DA has a rectangular shape, the disclosure is not limited thereto. The display area DA may have any of various shapes such as a circular shape, an oval shape, a polygonal shape, and a particular figure shape. The peripheral area PA may have the same shape as, or a different shape from the display area DA.

The display area DA may be an area for displaying an image. A plurality of main pixels PX may be arranged in the display area DA. Each of the pixels PX may include a display element such as an organic light-emitting device. Each of the pixels PX may emit, for example, red light, green light, or blue light. The pixel PX may be connected to a pixel circuit including a thin film transistor (TFT), a storage capacitor, etc. Such a pixel circuit may be connected to, for example, a scan line SL that transmits a scan signal, a data line DL that intersects with the scan line SL and transmits a data signal, and a driving voltage line PL that supplies a driving voltage. The data line DL and the driving voltage line PL may extend in a Y direction (hereinafter, a first direction), and the scan line SL may extend in an X direction (hereinafter, a second direction).

The pixel PX may emit light having a luminance corresponding to an electrical signal from an electrically connected pixel circuit. The display area DA may display a certain image by using light emitted by the pixel PX. For reference, the pixel PX used herein may be defined as a light-emission area that emits red light, green light, or blue light as described above.

The peripheral area PA may be an area where no pixels PX are arranged, and may correspond to an area where no images are displayed. Power supply wiring for driving pixels PX may be disposed in the peripheral area PA. In addition, pads may be arranged in the peripheral area PA. An integrated circuit device, such as a driver IC or a printed circuit board including a driving circuit unit, and the pads may be electrically connected to each other in the peripheral area PA.

The display panel 10 may include a substrate 100. It may be considered that the substrate 100 has the display area DA and the peripheral area PA. A detailed description of the substrate 100 is provided herein.

A plurality of transistors may be arranged in the display area DA. A first terminal of a transistor may be a source electrode or a drain electrode, and a second terminal thereof may be an electrode different from the first terminal according to a type (N-type or P-type) and/or an operating condition of the transistor. For example, when the first terminal is a source electrode, the second terminal may be a drain electrode.

The plurality of transistors may include a driving transistor, a data write transistor, a compensation transistor, an initialization transistor, and an emission control transistor. The driving transistor may be connected between the driving voltage line PL and the organic light-emitting device (OLED). The data write transistor may be connected to the data line DL. The driving transistor and may perform a switching operation of transmitting a data signal transmitted through the data line DL.

The compensation transistor may be turned on according to a scan signal received through the scan line SL to connect the driving transistor to the OLED and compensate for a threshold voltage of the driving transistor.

The initialization transistor may be turned on according to a scan signal received through the scan line SL to transmit an initialization voltage to a gate electrode of the driving transistor and initialize the gate electrode of the driving transistor. The scan line connected to the initialization transistor may be a separate scan line different from the scan line connected to the compensation transistor.

The emission control transistor may be turned on according to an emission control signal received through an emission control line so that a driving current flows through the OLED.

The organic light-emitting device may include a pixel electrode (e.g., an anode) and an opposite electrode (e.g., a cathode), and may receive a voltage from the pixel electrode (e.g., the anode) and the opposite electrode (e.g., the cathode). The organic light-emitting device may receive the driving current from the driving transistor to emit light and display an image.

An organic light-emitting display apparatus will now be illustrated and described as a display apparatus according to an embodiment, but a display apparatus according to the disclosure is not limited thereto. According to an embodiment, the display apparatus of the disclosure may be an inorganic light-emitting display, a quantum dot light-emitting display, or the like. For example, an emission layer of a display device included in the display apparatus may include an organic material or may include an inorganic material. The display apparatus may include an emission layer and quantum dots located on the path of light emitted by the emission layer.

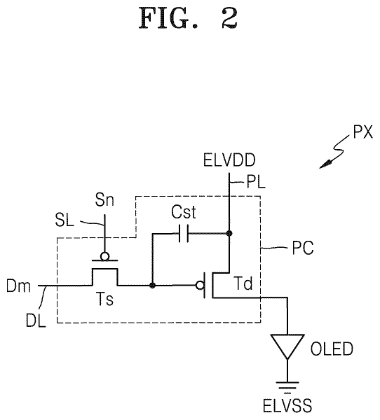

FIG. 2 is an equivalent circuit diagram of a pixel of the display apparatus of FIG. 1.

Referring to FIG. 2, each pixel PX may include a pixel circuit PC connected to a scan line SL and a data line DL, and an organic light-emitting device OLED connected to the pixel circuit PC.

The pixel circuit PC may include a driving thin-film transistor Td, a switching thin-film transistor Ts, and a storage capacitor Cst. The switching thin-film transistor Ts may be connected to the scan line SL and the data line DL, and may transmit, to the driving thin-film transistor Td, a data signal Dm received via the data line DL according to a scan signal Sn received via the scan line SL.

The storage capacitor Cst may be connected to the switching thin-film transistor Ts and a driving voltage line PL, and may store a voltage corresponding to a difference between a voltage received from the switching thin-film transistor Ts and a first power supply voltage ELVDD (or a driving voltage) supplied to the driving voltage line PL.

The driving thin-film transistor Td may be connected to the driving voltage line PL and the storage capacitor Cst, and may control a driving current flowing from the driving voltage line PL to the organic light-emitting device OLED, in accordance with a voltage value stored in the storage capacitor Cst. The organic light-emitting device OLED may emit light having a certain brightness according to the driving current.

The organic light-emitting device OLED may receive a second power supply voltage ELVSS (or a common voltage). For example, the organic light-emitting device OLED may receive the second power supply voltage ELVSS (or common voltage) through an opposite electrode (cathode), and the organic light-emitting device OLED may emit light having a certain luminance according to a driving current, which may be controlled according to a voltage difference between the first power supply voltage ELVDD (or driving voltage) and the second power supply voltage ELVSS (or common voltage).

Although a case in which the pixel circuit PC includes two thin-film transistors and one storage capacitor is illustrated in FIG. 2, embodiments are not limited thereto. For example, the pixel circuit PC may include two or more storage capacitors, and may include three or more thin-film transistors.

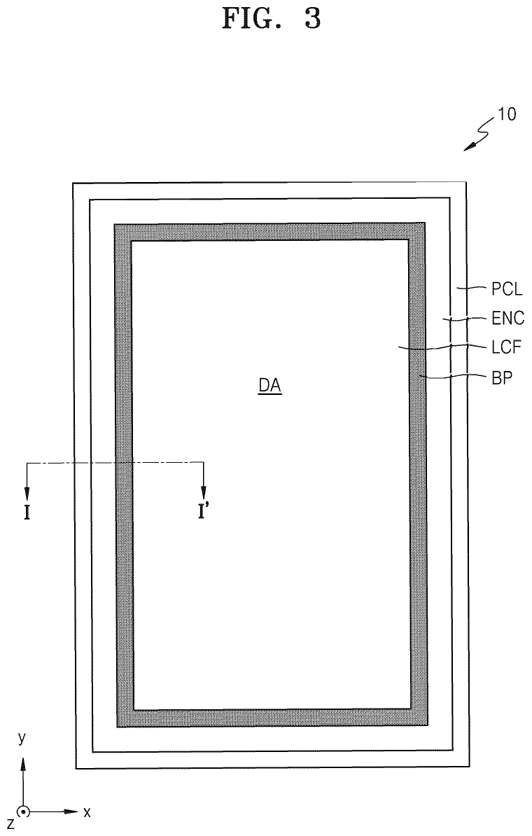

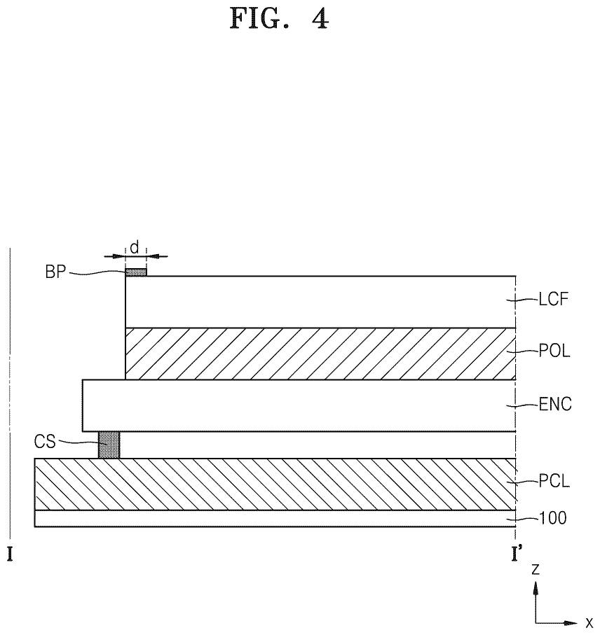

FIG. 3 is a plan view showing the optical functional layer of the display panel of FIG. 1. FIG. 4 is a cross-sectional view schematically showing a cross-section taken along line I-I′ of FIG. 3.

To the extent that FIG. 3 and FIG. 4 are the same as, or overlap with descriptions given elsewhere herein, redundant descriptions may be omitted.

As shown in FIG. 3 and FIG. 4, the display panel 10 of the display apparatus according to an embodiment may include the substrate 100, a pixel circuit layer PCL, an encapsulation layer ENC, a polarization layer POL, and an optical functional layer LCF. The pixel circuit layer PCL, the encapsulation layer ENC, the polarization layer POL, and the optical functional layer LCF may be sequentially stacked. For example, the pixel circuit layer PCL may be disposed on the substrate 100, the encapsulation layer ENC may be disposed on the pixel circuit layer PCL, the polarization layer POL may be disposed on the encapsulating layer ENC, and the optical functional layer LCF may be disposed on the polarization layer POL.

The encapsulation layer ENC may be a layer for encapsulating the substrate 100 (or the pixel circuit layer PCL). The encapsulation layer ENC may be an inorganic layer containing a type of inorganic material or an organic layer containing an organic material. Alternatively, the encapsulation layer ENC may include a plurality of layers composed by stacking an inorganic layer and an organic layer. The encapsulation layer ENC may be fixed by a sealing member CS disposed on the pixel circuit layer PCL. The encapsulation layer ENC may encapsulate at least a portion of the substrate 100 or the pixel circuit layer PCL in combination with the sealing member CS.

The encapsulation layer ENC may cover light-emitting elements of the pixel circuit layer PCL. The encapsulation layer ENC may inhibit or prevent oxygen and moisture from permeating into the light-emitting elements. The encapsulation layer ENC may include a plurality of insulating layers, and may include a plurality of inorganic layers (not shown) and a plurality of organic layers (not shown). In this case, the plurality of inorganic layers (not shown) may include at least one of silicon oxide, silicon nitride, silicon oxynitride, aluminum oxide, titanium oxide, zirconium oxide, and tin oxide. The plurality of organic layers (not shown) may include one of acryl, polyimide (PI), polyamide (PA), and benzocyclobutene (BCB).

The polarizing layer POL may be disposed on at least a portion of an upper surface of the encapsulating layer ENC. The polarizing layer POL may prevent or suppress reflection of external light incident on the display apparatus. The polarizing layer POL may improve the display quality of the display apparatus. To this end, the polarization layer POL may cover at least the display area of the display apparatus.

For example, the polarization layer POL may transform natural light (e.g., non-polarized light) or arbitrarily polarized light into linearly-polarized light having a specific direction, and may further include a linear polarization layer (not shown) for reducing reflection of external light, and a phase difference layer for shifting the phase of the incident light by about ¼). Accordingly, the phase difference layer (not shown) may change linearly-polarized light into circularly-polarized light, or change circularly-polarized light into linearly-polarized light.

The optical functional layer LCF may be disposed on the polarizing layer POL. The optical functional layer LCF may have light directionality to control the path of external light or reflection light, and may improve light efficiency by diffusing the reflection light. A detailed description of the optical functional layer LCF is described herein.

A reference pattern BP may be disposed on an upper surface of the optical functional layer LCF. The reference pattern BP may be disposed at the edge of the optical functional layer LCF. For example, the reference pattern BP may be printed on the upper surface of the optical functional layer LCF. The reference pattern BP may be printed at the edge of the optical functional layer LCF.

The reference pattern BP may be a reference marker for accurately indicating the edge (or border) of the optical functional layer LCF. The reference pattern BP may be configured to be recognized by an inspection system. The reference pattern BP may have a characteristic that may be recognized by the inspection system. For example, the reference pattern BP may have a color, luminance, or reflectivity that may be recognized by the inspection system. The reference pattern BP may be formed through an inkjet printing process, but may be formed through various methods without being limited by the material, color or processing method thereof.

In a plan view, the reference pattern BP may have a width d. For example, the width d of the reference pattern BP may be about 10 micrometers to about 150 micrometers, or may be about 100 micrometers. The width d of the reference pattern BP may be consistent around the edge of the optical functional layer LCF. The width d of the reference pattern BP may vary around the edge of the optical functional layer LCF. For example, the width d of the reference pattern BP may be different between at least two different edges of the optical functional layer LCF.

In general, the border of the optical functional layer LCF may not be straight, and the border of the optical function layer LCF may have a bumpy shape or a wavy shape. In general, an extent of the border of the optical functional layer LCF may have a variation of about 10 micrometers over a length the border (e.g., an edge). Therefore, the width d of the reference pattern BP may have a size equal to or greater than the variation in the extent of the border of the optical functional layer LCF in a plan view. In addition, considering a recognition sensitivity of the inspection system, the width d of the reference pattern BP may be about 10 micrometers or more.

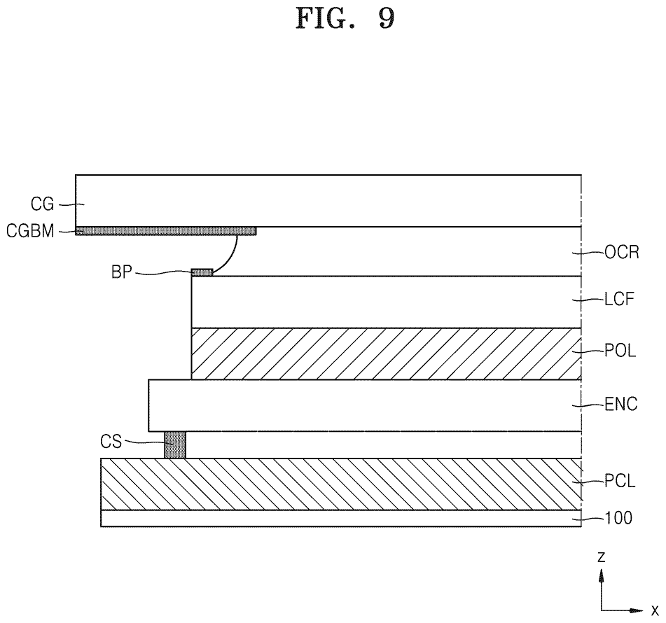

When the width d of the reference pattern BP is greater than about 150 micrometers, the reference pattern BP may have a thickness that is not completely obscured by a window layer CG (see FIG. 9). When the reference pattern BP is identified by a user in a final product, this may have a negative impact on a display quality, such as making a bezel appear thicker.

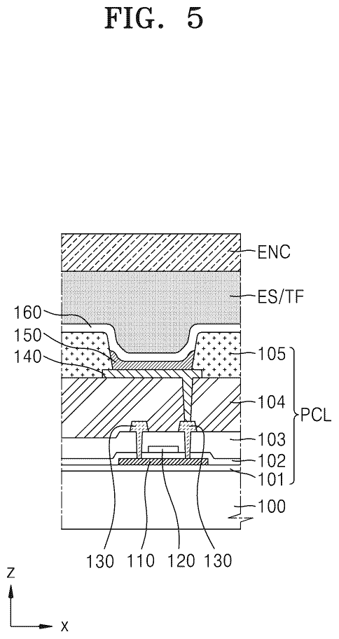

FIG. 5 is a schematic cross-sectional view of a portion of the display apparatus of FIG. 1.

As described above, the substrate 100 may include the display area DA and areas corresponding to the peripheral area PA around the display area DA. The substrate 100 may include various materials having flexible or bendable characteristics. For example, the substrate 100 may include glass, metal, or polymer resin. The substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure. Each layer may include a polymer resin. A barrier layer including an inorganic material (silicon oxide, silicon nitride, silicon oxynitride, or the like) may be located between layers of the multi-layered structure. The substrate 100 is not limited, and various modifications may be made.

A buffer layer 101 may be disposed on the substrate 100. The buffer layer 101 may serve as a barrier layer and/or a blocking layer. For example, the buffer layer 101 may inhibit or prevent diffusion of impurity ions. The buffer layer 101 may inhibit or prevent penetration of moisture or external air. The buffer layer 101 may be used as a barrier layer and/or a blocking layer planarizing an upper surface of the substrate 100. The buffer layer 101 may include silicon oxide, silicon nitride, or silicon oxynitride. The buffer layer 101 may control a heat transfer rate during a crystallization process for forming a semiconductor layer 110, such that the semiconductor layer 110 may be uniformly crystallized.

The semiconductor layer 110 may be disposed on the buffer layer 101. The semiconductor layer 110 may be formed of polysilicon. The semiconductor layer 110 may include a channel region undoped with impurities and a source region and a drain region both doped with impurities and respectively formed sides of the channel region. The impurities may vary depending on the type of thin film transistor, and may be N-type impurities or P-type impurities. Although not shown in FIG. 5, the display apparatus according to the inventive concept may further include one or more additional semiconductor layers disposed on another layer.

A gate insulating layer 102 may be disposed on the semiconductor layer 110. The gate insulating layer 102 may be configured to secure insulation between the semiconductor layer 110 and a gate layer 120. The gate insulating layer 102 may include an inorganic material such as silicon oxide, silicon nitride, and/or silicon oxynitride, and may be interposed between the semiconductor layer 110 and the gate layer 120. The gate insulating layer 102 may be a conformal layer. For example, the gate insulating layer 102 may have a shape corresponding to the surface of the substrate 100. The gate insulating layer 102 may have a structure in which contact holes are formed at preset portions. As such, an insulating layer including an inorganic material may be formed via chemical vapor deposition (CVD) or atomic layer deposition (ALD). This may be equally applied to embodiments described herein and modifications thereof.

The gate layer 120 may be disposed on the gate insulating layer 102. The gate layer 120 may be disposed at a position vertically overlapping the semiconductor layer 110, and may include at least one metal of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu). A detailed description of the gate layer 120 is described herein. Although not shown in FIG. 5, the display apparatus according to the inventive concept may further include another gate layer disposed on another layer.

An interlayer insulating layer 103 may be disposed on the gate layer 120. The interlayer insulating layer 103 may cover the gate layer 120. The interlayer insulating layer 103 may be formed of an inorganic material. For example, the interlayer insulating layer 103 may be metal oxide or metal nitride. For example, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like. According to some embodiments, the interlayer insulating layer 103 may have a dual structure of SiOₓ/SiN_{y} or SiNₓ/SiO_{y}.

A conductive layer 130 may be disposed on the interlayer insulating layer 103. The conductive layer 130 may serve as an electrode that is connected to source/drain regions of a semiconductor layer through a through hole included in the gate insulating layer 102 and the interlayer insulating layer 103.

The conductive layer 130 may include at least one metal selected from aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the conductive layer 130 may include a Ti layer, an Al layer, and/or a Cu layer. For example, the conductive layer 130 may include a Ti/Al/Ti structure.

Although not shown in FIG. 5, the display apparatus according to the inventive concept may further include an additional conductive layer disposed on another layer. The additional conductive layer may be, for example, a wiring layer that functions as wiring. The additional conductive layer may include the same material as the conductive layer 130, and have the same layer structure as the conductive layer 130.

An organic insulating layer 104 may be disposed on the interlayer insulating layer 103 and the conductive layer 130. The organic insulating layer 104 may be an organic insulating layer that covers an upper portion of the conductive layer 130 and has a substantially flat upper surface, which may serve as a planarization layer. The organic insulating layer 104 may include an organic material, such as, acryl, benzocyclobutene (BCB), or hexamethyldisiloxane (HMDSO). Various modifications may be made to the organic insulating layer 104. For example, the organic insulating layer 104 may include a single layer or multiple layers.

Although not shown in FIG. 5, the display apparatus according to the inventive concept may further include an additional organic insulating layer disposed on another layer. The additional organic insulating layer may be disposed on the additional conductive layer described above, and may cover the top of the additional conductive layer to serve as a planarization layer. The additional organic insulating layer may include the same material as the organic insulating layer 104, and have the same layer structure as the organic insulating layer 104.

A pixel electrode 140 may be disposed on the organic insulating layer 104. Alternatively, the pixel electrode 140 may be disposed on the additional organic insulating layer. However, for convenience of explanation, it may be assumed that the pixel electrode 140 is disposed on the organic insulating layer 104.

The pixel electrode 140 may be connected to the conductive layer 130 through a contact hole formed in the organic insulating layer 104. A display element may be disposed on the pixel electrode 140. An organic light-emitting device OLED may be used as the display element. In other words, the organic light-emitting device OLED may be disposed on, for example, the pixel electrode 140. The pixel electrode 140 may include a light-transmissive conductive layer formed of light-transmissive conductive oxide such as ITO, In₂O₃, or IZO, and a reflective layer formed of a metal such as Al or Ag. For example, the pixel electrode 140 may have a layered structure of ITO/Ag/ITO.

A pixel defining layer 105 may be disposed on the organic insulating layer 104. The pixel defining layer 105 may be disposed to cover an edge of the pixel electrode 140. For example, the pixel defining layer 105 may cover a sidewall of the pixel electrode 140 extending in a vertical direction (e.g., the Z direction). The pixel defining layer 105 may have an opening corresponding to a pixel, and the opening may be formed to expose at least a portion of the pixel electrode 140. For example, the pixel defining layer 105 may expose at least a central portion of the pixel electrode 140. The opening may be defined by the pixel defining layer 105.

The pixel defining layer 105 may include, for example, an organic material such as polyimide or hexamethyldisiloxane (HMDSO). A spacer (not shown) may be disposed on the pixel defining layer 105. The spacer may be positioned on the peripheral area PA, but may also be positioned on the display area DA. The spacer may prevent the organic light-emitting device OLED from being damaged due to sagging of a mask in a manufacturing process using the mask. The spacer may include an organic insulative material and may be a single layer or multiple layers.

An intermediate layer 150 and an opposite electrode 160 may be disposed in the opening in the pixel defining layer 105. The intermediate layer 150 may include a low molecular weight or high molecular weight material. When the intermediate layer 150 includes a low-molecular weight material, the intermediate layer 150 may include a hole injection layer, a hole transport layer, an emission layer, an electron transport layer, and/or an electron injection layer. When the intermediate layer 150 includes a high-molecular weight material, the intermediate layer 150 may generally have a structure including an HTL and an EML.

The intermediate layer 150 is not limited to the structure described herein, and may have any of various other structures. For example, at least one of the layers that constitute the intermediate layer 150 may be integrally formed with the opposite electrode 160. According to another embodiment, the intermediate layer 150 may include a layer patterned to correspond to each of a plurality of pixel electrodes 140.

The opposite electrode 160 may include a light-transmissive conductive layer formed of a light-transmissive conductive oxide such as ITO, In₂O₃, or IZO. The pixel electrode 140 may be used as an anode electrode, and the opposite electrode 160 may be used as a cathode electrode. Alternatively, the pixel electrode 140 may be used as a cathode electrode, and the opposite electrode 160 may be used as an anode electrode.

The opposite electrode 160 may be disposed in the display area DA. The opposite electrode 160 may cover the entire display area DA. In other words, the opposite electrode 160 may be integrally formed to cover a plurality of pixels.

The pixel circuit layer PCL may include layers disposed on the substrate 100. The pixel circuit layer PCL may include, for example, the semiconductor layer 110, the gate insulating layer 102, the gate layer 120, the interlayer insulating layer 103, the conductive layer 130, the organic insulating layer 104, the pixel electrode 140, the pixel defining layer 105, the intermediate layer 150, and the opposite electrode 160. In some cases, the pixel circuit layer PCL may include the buffer layer 101. The pixel circuit layer PCL is a concept introduced for convenience of explanation. The pixel circuit layer PCL may be understood as a layer disposed on the substrate 100 and including at least one light-emitting pixel.

The encapsulation layer ENC may be disposed on the pixel circuit layer PCL, and an empty space (ES) or a transparent filler (TF) may be disposed between the pixel circuit layer PCL and the encapsulation layer ENC.

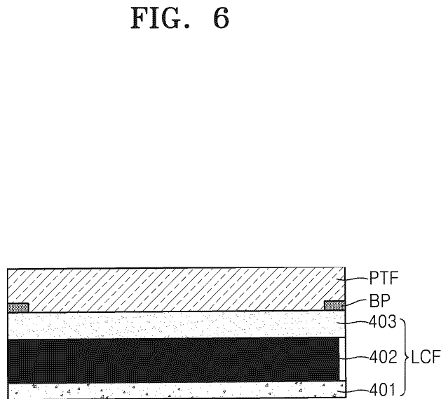

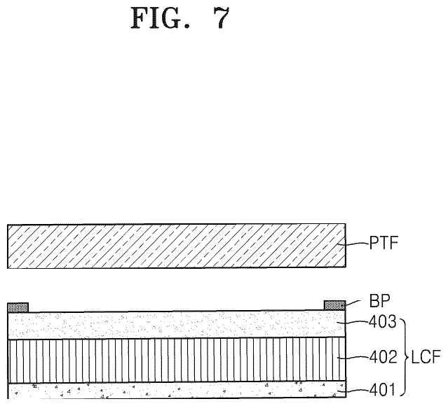

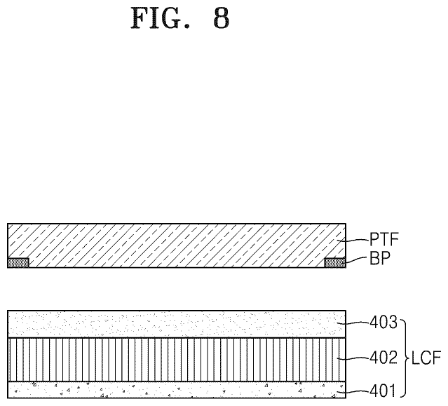

FIG. 6, FIG. 7, and FIG. 8 are cross-sectional views schematically showing an example in which a protective film layer is disposed on the optical functional layer of FIG. 3 and FIG. 4.

As shown in FIGS. 6 through 8, the optical functional layer LCF may include a first adhesive layer 401, a light control layer 402, and a cover layer 403. The first adhesive layer 401 may be disposed on the polarization layer POL. The light control layer 402 may be disposed on the first adhesive layer 401. The cover layer 403 may be disposed on the light control layer 402.

The first adhesive layer 401 may be disposed between the polarization layer POL and the light control layer 402, and may bond an upper surface of the polarization layer POL to a lower surface of the light control layer 402. For example, the first adhesive layer 401 may be an adhesive layer manufactured by applying a liquid adhesive material and curing the liquid adhesive material, or may be a separately manufactured adhesive sheet. For example, the first adhesive layer 401 may include a pressure sensitive adhesive (PSA), an optically clear adhesive (OCA), or an optically clear resin (OCR).

The light control layer 402 may have a light directionality characteristic. For example, the light control layer 402 may control the path of light emitted from the light control layer 402. The light exiting from the light control layer 402 may be referred to as external light or reflected light. The light emitted from the light control layer 402 may have a predetermined angle or may be polarized with respect to a direction perpendicular to the polarization layer POL. The light control layer 402 may have a window layer including a light blocking area. In an example, the path of the light emitted from the light control layer 402 may be guided in the direction of the user's viewing angle by the light control layer 402, and the usage efficiency of the light may be increased.

The cover layer 403 may be disposed on the light control layer 402. The cover layer 403 may protect the light control layer 402 from the outside. The cover layer 403 may be a layer on which the reference pattern BP may be printed. The cover layer 403 may include a material having a high light transmittance. For example, the cover layer 403 may include polyimide (PI), cyclic olefin polymer (COP), polycabonate (PC), polyethyleneterephthalate (PET), polyethylenapthanate (PEN), polynorborneen (PNB), or polyethersulfone (PES), or may include a combination of some of the aforementioned materials. Alternatively, the cover layer 403 may include a resin.

A protective film layer PTF may be disposed on the optical functional layer LCF. For example, the protective film layer PTF may be disposed on the cover layer 403 included in the optical functional layer LCF. The protective film layer PTF may be a detachable layer. For example, the optical functional layer LCF may be provided as a unit including the protective film layer PTF disposed thereon. The protective film layer PTF may be configured to protect an upper surface of the optical functional layer LCF from external substances or external shocks. For example, the protective film layer PTF may protect the upper surface of the optical functional layer LCF during transport. The protective film layer PTF may be removed during a display apparatus manufacturing process. The protective film layer PTF may be removed after an alignment inspection process using a vision inspection device which is described herein.

As shown in FIG. 6, the protective film layer PTF may be disposed on the optical functional layer LCF. The protective film layer PTF may cover the reference pattern BP. The reference pattern BP may be disposed on the cover layer 403. In a cross-sectional view, the reference pattern BP may be disposed between the light control layer 402 and the protective film layer PTF. The reference pattern BP may be disposed between the cover layer 403 and the protective film layer PTF.

As shown in FIG. 7, the protective film layer PTF may be removed. The protective film layer PTF may be removed during the display apparatus manufacturing process. In an example in which the reference pattern BP is printed on an upper surface of the optical functional layer LCF or an upper surface of the cover layer 403, when the protective film layer PTF is removed, the reference pattern BP may remain on the upper surface of the optical functional layer LCF. For example, when the protective film layer PTF is removed, the protective film layer PTF and the reference pattern BP may be separated from each other, and the reference pattern BP may not be removed from the cover layer 403 or the optical functional layer LCF. In an example, the reference pattern BP may remain disposed on the optical functional layer LCF following the removal of the protective film layer PTF, and the reference pattern BP may be covered by the window layer CG.

As shown in FIG. 8, the protective film layer PTF may be removed during the display apparatus manufacturing process. In an example, the reference pattern BP may be removed together with the protective film layer PTF. To this end, the reference pattern BP may not be printed on the upper surface of the optical functional layer LCF or the upper surface of the cover layer 403, but may be printed on the lower surface of the protective film layer PTF. In an example where the reference pattern BP is printed on a surface of the protective film layer PTF, the reference pattern BP may be aligned with an edge of the optical functional layer LCF. Therefore, an alignment of the optical functional layer LCF and the polarization layer POL may be determined even when the reference pattern BP is printed on a surface of the protective film layer PTF. In an example in which the reference pattern BP is removed along with the protective film layer PTF, or removed subsequent to the protective film PTF, another component for separately covering the reference pattern BP in a later operation may be omitted.

Although not shown in FIG. 8, the reference pattern BP may be printed on the upper surface of the protective film layer PTF opposite the lower surface of the protective film layer PTF. When the reference pattern BP is printed on the lower surface or upper surface of the protective film layer PTF, the reference pattern BP may be disposed at an area corresponding to the edge of the optical functional layer LCF. Even when the reference pattern BP is printed on the lower surface or upper surface of the protective film layer PTF, the reference pattern BP may serve as a reference marker for identifying the edge of the optical functional layer LCF.

FIG. 9 is a cross-sectional view schematically showing an example in which a window layer may be disposed on the display panel of FIG. 4. Redundant descriptions of components identified by the same reference numeral in the drawings (for example, with reference to FIG. 6) may be omitted.

As shown in FIG. 9, the window layer CG may be disposed on the optical functional layer LCF. The window layer CG may be made of a transparent material such as glass.

The window layer CG may be divided into a transmission area (not shown) and a light blocking area (not shown) in a plan view. In a plan view, the light blocking area (not shown) may be disposed to surround the transmission area (not shown). The light blocking area may be defined by a light blocking material layer CGBM disposed on the lower surface of the window layer CG. In a plan view, the light blocking area may refer to an area where the light blocking material layer CGBM is disposed. The transmission area may refer to an area where the light blocking material layer CGBM is not disposed in a plan view.

The light blocking material layer CGBM may be disposed on the lower surface of the window layer CG. The light blocking material layer CGBM may be disposed at the edge of the window layer CG. The light blocking material layer CGBM may be disposed at the edge of the window layer CG and the light blocking material layer CGBM may extend toward a central portion of the window layer CG with a specific width.

In a plan view, the light blocking material layer CGBM and the reference pattern BP may overlap each other. For example, the reference pattern BP may be obscured by the light blocking material layer CGBM when viewed from the outside of the display apparatus. For example, the light blocking material layer CGBM may have a width greater than or equal to a width of the reference pattern BP.

The light blocking material layer CGBM may be a black matrix, and may include various materials capable of absorbing at least a portion of light. For example, the light blocking material layer CGBM may include at least one of carbon black, graphite, a chromium-based material, a dye, a metal reflective film, and a light absorption film.

A second adhesive layer may be disposed between the window layer CG and the optical functional layer LCF. For example, the second adhesive layer may include a pressure sensitive adhesive (PSA), an optically clear adhesive (OCA), or an optical clear resin (OCR). In FIG. 9, the second adhesive layer is illustrated as an optical clear resin (OCR), however the description is not limited thereto. For example, the optical clear resin (OCR) may be replaced by a pressure sensitive adhesive (PSA) or an optically clear adhesive (OCA). The second adhesive layer may be located between the lower surface of the window layer CG and the upper surface of the optical functional layer LCF. The second adhesive layer may bond the lower surface of the window layer CG to the upper surface of the optical functional layer LCF.

At least one of the reference pattern BP and the light blocking material layer CGBM may function to inhibit the flow of the optical clear resin (OCR) to an edge of the optical functional layer LCF. While the reference pattern BP is shown to have a rectangular shape in cross-section, the reference pattern BP may have other shapes. For example, the reference pattern BP may have a shape configured to inhibit the flow of the optical clear resin (OCR) to the edge of the optical functional layer LCF. For example, the reference pattern BP may have a dome shape in cross-section. In an example, the reference pattern BP may have a substantially linear edge disposed along the edge of the optical functional layer LCF and a wavy edge disposed oppose the linear edge in a plan view. In another example, the reference pattern BP may be provided as a first reference pattern disposed at the edge of the optical functional layer LCF and a second reference pattern disposed adjacent to the first reference pattern. In yet another example, the first reference pattern may be linear, along edge of the optical functional layer LCF and the second reference pattern may have a wavy shape in a plan view.

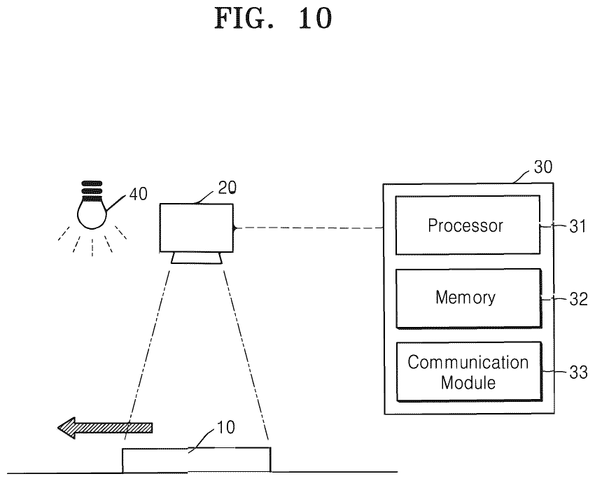

FIG. 10 is a conceptual diagram schematically illustrating an inspection system according to an embodiment.

For reference, in the description of FIG. 10, redundant descriptions of the same or overlapping matters as those described above may be omitted.

As shown in FIG. 10, the inspection system for inspecting the display panel 10 according to an embodiment may include a sensing device 20 and a computing device 30. For example, the inspection system may be an optical functional layer alignment inspection system. The sensing device 20 may generate image data about the upper surface of the display panel 10. The computing device 30 may receive the image data and perform a vision recognition operation based on the image data.

The display panel 10 has been described with reference to FIGS. 1 through 8, and a redundant description thereof may be omitted. The optical functional layer LCF and the polarization layer POL may be aligned so that they overlap each other in a plan view. An alignment state may be derived by the computing device 30 according to a result of detecting the edge of the optical functional layer LCF and the edge of the polarization layer POL by optical recognition. However, it may be difficult to clearly distinguish between the edge of the optical functional layer LCF and the edge of the polarization layer POL using optical recognition.

The display panel 10 may be disposed on a vision inspection stage of the inspection system shown in FIG. 10. The display panel 10 may be in a state before the window layer CG is formed. The display panel 10 disposed on the vision inspection stage may be in a state where the substrate 100, the pixel circuit layer PCL, the encapsulation layer ENC, the polarization layer POL, and the optical functional layer LCF are sequentially stacked (see for example, FIG. 4). In an example, the edge of the optical functional layer LCF may be distinguished using the reference pattern BP disposed at the edge of the optical functional layer LCF. In a case where the edge of the optical functional layer LCF and the edge of the polarization layer POL are aligned in the vertical direction (e.g., the Z direction), the edge of the polarization layer POL may be distinguished using the reference pattern BP disposed at the edge of the optical functional layer LCF. In some cases, as shown in FIG. 8, the display panel 10 disposed on the vision inspection stage may include the protective film layer PTF. The protective film layer PTF may protect the upper surface of the optical functional layer LCF. When further including the protective film layer PTF, the reference pattern BP of the display panel 10 may be printed on the upper surface of the optical functional layer LCF, or may be printed on a surface of the protective film layer PTF. For example, the reference pattern BP may be printed on a lower surface of the protective film layer PTF.

The sensing device 20 may be a device for generating image data. The image data may be at least one image, or may be a frame image. For example, the sensing device 20 may refer to an optical camera, an infrared camera, or an ultraviolet camera, or any device that detects an object by using electromagnetic radiation, such as radar or lidar. The sensing device 20 may be an optical camera.

The computing device 30 may receive the image data from the sensing device 20. The computing device 30 may perform an operation for recognizing the reference pattern BP in the image data. For example, the computing device 30 may execute a pre-stored algorithm. The computing device 30 may obtain information on an alignment state of the optical functional layer LCF based on the reference pattern BP.

The information on the alignment state of the optical functional layer LCF may be classified. For example, the information on the alignment state may be indicative of the edge of the optical functional layer LCF protruding outside the edge of the polarization layer POL in the image data. In another case, information on the alignment state may be indicative of the edge of the optical functional layer LCF being disposed inside the edge of the polarization layer POL in the image data. In yet another case, information on the alignment state may be indicative of the edge of the optical functional layer LCF coinciding with the edge of the polarization layer POL in the image data. In this case, the edge of the optical functional layer LCF and the edge of the polarization layer POL may correspond to each other in the vertical direction (e.g., the Z direction). For example, the alignment state of a left edge of the optical functional layer LCF in a plan view may be defined based on a relative position with respect to a left edge of the polarization layer in a plan view.

When one edge of the optical functional layer LCF is disposed outside the edge of the polarization layer POL (e.g., when one edge of the optical functional layer LCF is disposed outside one edge of the polarization layer POL), the other edge of the optical functional layer LCF that is opposite to the edge thereof may be disposed inside the edge of the polarization layer POL. Accordingly, the computing device 30 may recognize the reference pattern BP disposed on a side of the edge of the optical functional layer LCF from the image data, and may obtain alignment state information based on the side of the edge of the optical functional layer LCF.

The computing device 30 may define the display panel 10 as defective or normal based on the alignment state information. For example, the computing device 30 may define the display panel 10 as normal when the alignment state is indicative of the edge of the optical functional layer LCF coinciding with the edge of the polarization layer POL in the image data. For example, coincidence may be determined when the reference pattern BP overlaps an edge of the polarization layer POL, for example, when the edge of the polarization layer POL is concealed by the reference pattern BP. In this way, a precision of the alignment (e.g., a tolerance of alignment) may be controlled according to a width from the reference pattern BP.

The computing device 30 may transmit the display panel 10 to a predetermined process according to the defined state or may perform labeling on the display panel 10. For example, the computing device 30 may classify the display panel 10 as having aligned layers, and may cause the display panel 10 to be advanced to a further process. For example, the computing device 30 may classify the display panel 10 as having aligned layers, and may cause the display panel 10 to be advanced for packaging, for implementation in an electronic device, etc. In a case where the computing device 30 classifies the display panel 10 as being misaligned (e.g., the alignment state is abnormal), the computing device 30 may cause the display panel 10 to be advanced for corrective processing or recycling, or removed from further processing.

To perform these operations, the computing device 30 may include a processor 31, a memory 32, and a communication module 33.

The memory 32 may store data that supports various functions of the computing device 30. The memory 32 may store an application program or application that may be executed by the computing device 30, data for operations of the computing device 30, or other instructions. The application program may be downloaded to the computing device 30, for example, from an external server through wireless communication. The application program may be stored in the memory 32 installed in the computing device 30, and executed by the processor 31 to perform an operation (or function) of the computing device 30.

The memory 32 may include at least one type of storage medium selected from among a flash memory type, a hard disk type, a solid state disk (SSD) type, a silicon disk drive (SDD) type, a multimedia card micro type, a card type memory (for example, a secure digital (SD) or extreme digital (XD) memory), a random access memory (RAM), a static random access memory (SRAM), a read-only memory (ROM), an electrically erasable programmable ROM (EEPROM), a programmable ROM (PROM), magnetic memory, a magnetic disk, and an optical disk. The memory 32 may include a cloud storage which may perform a storage function on a network.

The processor 31 may execute instructions and process information by processing signals, data, information, etc. input or output by the computing device 30. The processor 31 may control one or more other components by executing the instructions stored in the memory 32. The processor 31 may execute the instructions stored in the memory 32. For example, the processor 31 may run an application program stored in the memory 32.

The processor 31 may be a component capable of performing calculations and controlling one or more other devices. The processor 31 may mainly refer to a central processing unit (CPU), an application processor (AP), a graphics processing unit (GPU), or the like. The CPU, the AP, or the GPU may include one or more cores therein, and the CPU, the AP, or the GPU may operate using an operating voltage and a clock signal.

The communication module 33 may transmit/receive information. The information may be transmitted/received to/from a base station or another component including a communication function through an antenna. In this case, the communication module 33 may include a modulator, a demodulator, a signal processor, or the like. Alternatively, the communication module 33 may perform a communication function, wired or wireless.

Wireless communication may refer to communication using a wireless communication network and communication protocol such as 3GPP, LTE, 5G, or 6G. However, the present specification may utilize a pre-installed communication network without being bound by such a wireless communication method.

The wireless communication may refer to short range communication. In this case, the wireless communication may include Bluetooth, Bluetooth Low Energy (BLE), beacon, Radio Frequency Identification (RFID), Infrared Data Association (IrDA), Ultra-Wideband (UWB), ZigBee, etc.

As shown in FIG. 10, the inspection system may further include a lighting device 40. The lighting device 40 may aid in obtaining clear image data. The reference pattern BP may have a color according to the color of the lighting device 40. For example, the color of the reference pattern BP may have a complementary color to the color of light emitted from the lighting device 40. This is only an example for aiding understanding, and the scope of rights of this specification is not limited by the example.

According to an embodiment as described herein, an inspection system capable of inspecting the alignment state of an optical functional layer and a polarization layer through vision recognition and its vision inspection system may be implemented. Of course, the scope of the disclosure is not limited thereto.

It should be understood that embodiments described herein should be considered in a descriptive sense only and not for purposes of limitation. Descriptions of features or aspects within embodiments should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a pixel circuit layer;
a polarization layer disposed on the pixel circuit layer;
an optical functional layer disposed on the polarization layer; and
a reference pattern aligned with an edge of the optical functional layer.

2. The display apparatus of claim 1, further comprising a substrate,
wherein the pixel circuit layer is disposed on the substrate, and
the reference pattern is printed on an upper surface of the optical functional layer.

3. The display apparatus of claim 2, further comprising a protective film layer disposed on the optical functional layer and the reference pattern.

4. The display apparatus of claim 1, further comprising a protective film layer disposed on the optical functional layer,
wherein the reference pattern is printed on a lower surface of the protective film layer.

5. The display apparatus of claim 1, further comprising a protective film layer disposed on the optical functional layer,
wherein the reference pattern is printed on an upper surface of the protective film layer.

6. The display apparatus of claim 1, wherein the optical functional layer further comprises:
a first adhesive layer disposed on the polarization layer;
a light control layer disposed on the first adhesive layer; and
a cover layer disposed on the light control layer.

7. The display apparatus of claim 6, wherein the reference pattern is printed on an upper surface of the cover layer.

8. The display apparatus of claim 1, wherein the reference pattern has a width of about 10 micrometers to about 150 micrometers in a plan view.

9. The display apparatus of claim 1, further comprising:
a window layer disposed on the optical functional layer; and
a light blocking material layer disposed on the window layer that overlaps the reference pattern in a plan view.

10. The display apparatus of claim 9, wherein the light blocking material layer is disposed on a lower surface of the window layer.

11. A vision inspection system comprising:
a sensing device configured to generate image data about an upper surface of a display panel comprising a polarization layer, an optical functional layer disposed on the polarization layer, and a reference pattern aligned with an edge of the optical functional layer; and
a computing device configured to receive the image data, recognize the reference pattern from the image data, and based on the reference pattern, obtain information on an alignment state of the optical functional layer.

12. The vision inspection system of claim 11, wherein the information on the alignment state is information corresponding to one of a case in which an edge of the optical functional layer protrudes outside an edge of the polarization layer in the image data, a case in which the edge of the optical functional layer is disposed inside the edge of the polarization layer in the image data, or a case in which the edge of the optical functional layer coincides with the edge of the polarization layer in the image data.

13. The vision inspection system of claim 12, wherein the computing device is configured to cause the display panel to be advanced to a further process upon obtaining information on the alignment state of the optical functional layer indicating that the edge of the optical functional layer coincides with the edge of the polarization layer in the image data.

14. The vision inspection system of claim 12, wherein the computing device is configured to cause the display panel to be advanced for one of corrective processing or recycling upon obtaining information on the alignment state of the optical functional layer indicating that the edge of the optical functional layer protrudes outside the edge of the polarization layer in the image data or that the edge of the optical functional layer is disposed inside the edge of the polarization layer in the image data.

15. A display apparatus comprising:
a substrate;
a pixel circuit layer disposed on the substrate;
a polarization layer disposed on the pixel circuit layer;
an optical functional layer disposed on the polarization layer; and
a reference pattern printed on an upper surface of the optical functional layer at an edge of the optical functional layer.

16. The display apparatus of claim 15, further comprising a protective film disposed on the optical functional layer and the reference pattern.

17. The display apparatus of claim 15, wherein the optical functional layer further comprises:
an adhesive layer disposed on the polarization layer;
a light control layer disposed on the adhesive layer; and
a cover layer disposed on the light control layer.

18. The display apparatus of claim 15, wherein the reference pattern has a width of about 10 micrometers to about 150 micrometers in a plan view.

19. The display apparatus of claim 15, further comprising:
a first adhesive layer disposed on the optical functional layer;
a window layer disposed on the first adhesive layer; and
a light blocking material layer disposed on a surface of the window layer that overlaps the reference pattern in a plan view.

20. The display apparatus of claim 19, wherein the light blocking material layer is disposed on a lower surface of the window layer.
